(19) United States
(12) Patent Application Publication
(10) Pub. No.: US 2022/0247155 A1
(43) Pub. Date: Aug. 4, 2022

(54) SEMICONDUCTOR OPTICAL DEVICE AND METHOD FOR MANUFACTURING THE SAME

(71) Applicant: Sumitomo Electric Industries, Ltd., Osaka (JP)

(72) Inventors: Takuo HIRATANI, Osaka-shi (JP); Naoki FUJIWARA, Osaka-shi (JP); Takehiko KIKUCHI, Osaka-shi (JP)

(73) Assignee: Sumitomo Electric Industries, Ltd., Osaka (JP)

(21) Appl. No.: 17/584,584

(22) Filed: Jan. 26, 2022

(30) Foreign Application Priority Data
Feb. 3, 2021 (JP) 2021-016063

(51) Int. Cl. H01S 5/227; H01S 5/10; H01S 5/02

(52) U.S. Cl. CPC H01S 5/227; H01S 5/021; H01S 5/1014

(57) ABSTRACT

A semiconductor optical device includes a substrate containing silicon, and a semiconductor element bonded to the substrate, the semiconductor element being formed of a compound semiconductor and having an optical gain. The substrate includes a waveguide and a first region connected to the waveguide in an extension direction of the waveguide. The first region includes a plurality of recesses and a plurality of protrusions. Each of the plurality of recesses is recessed in a thickness direction of the substrate compared to a surface of the substrate to which the semiconductor element is bonded. Each of the plurality of protrusions protrudes in the thickness direction of the substrate from bottom surfaces of the plurality of recesses. The plurality of recesses and the plurality of protrusions are alternately disposed in a direction intersecting with the extension direction of the waveguide. The semiconductor element is bonded to the first region.

### CROSS REFERENCE TO RELATED APPLICATIONS

This application claims priority based on Japanese Patent Application No. 2021-016063 filed on Feb. 3, 2021, and the entire contents of the Japanese patent application are incorporated herein by reference.

### TECHNICAL FIELD

The present disclosure relates to a semiconductor optical device and a method for manufacturing the same.

### BACKGROUND ART

A technique to bond a compound semiconductor element which has an optical gain, to a substrate such as a silicon on insulator (SOI) substrate (silicon photonics) on which waveguide is formed is disclosed in Soren Dhoore et al., “Demonstration of a Discretely Tunable III-V-on-Silicon Sampled Grating DFB Laser,” IEEE PHOTONICS TECHNOLOGY LETTERS, VOL. 28, NO. 21, NOV. 1, 2016.

### SUMMARY OF THE INVENTION

A semiconductor optical device according to the present disclosure include a substrate containing silicon, and a semiconductor element joined to the substrate, formed of a compound semiconductor, and having an optical gain. The substrate includes a waveguide and a first region connected to the waveguide in an extension direction of the waveguide. The first region includes a plurality of recesses and a plurality of protrusions. Each of the plurality of recesses is recessed in a thickness direction of the substrate compared to a surface of the substrate to which the semiconductor element is bonded. Each of the plurality of protrusions protrudes in the thickness direction of the substrate compared to bottom surfaces of the plurality of recesses. The plurality of recesses and the plurality of protrusions are alternately disposed in a direction intersecting with the extension direction of the waveguide. The semiconductor element is bonded to the first region.

A method for manufacturing a semiconductor optical device according to the present disclosure includes a step of preparing a substrate containing silicon, and a step of bonding a semiconductor element formed of a compound semiconductor and having an optical gain to the substrate. The substrate includes a waveguide and a first region connected to the waveguide in an extension direction of the waveguide. The first region includes a plurality of recesses and a plurality of protrusions. Each of the plurality of recesses is recessed in a thickness direction of the substrate compared to a surface of the substrate to which the semiconductor element is bonded. Each of the plurality of protrusions protrudes in the thickness direction of the substrate compared to bottom surfaces of the plurality of recesses. The plurality of recesses and the plurality of protrusions are alternately disposed in a direction intersecting with the extension direction of the waveguide. The semiconductor element is bonded to the first region in the step of bonding to the substrate.

### BRIEF DESCRIPTION OF THE DRAWINGS

FIG. 1A is a plan view illustrating a semiconductor optical device according to an embodiment.

FIG. 1B is a cross-sectional view taken along line A-A of FIG. 1A.

FIG. 1C is a cross-sectional view taken along line B-B of FIG. 1A.

FIG. 2A is a plan view illustrating a substrate.

FIG. 2B is a cross-sectional view taken along line A-A of FIG. 2A.

FIG. 3A is a plan view illustrating a method for manufacturing the semiconductor optical device.

FIG. 3B is a cross-sectional view taken along line A-A of FIG. 3A.

FIG. 3C is a cross-sectional view illustrating the method for manufacturing the semiconductor optical device.

FIG. 4A is a plan view illustrating the method for manufacturing the semiconductor optical device.

FIG. 4B is a cross-sectional view taken along line A-A of FIG. 4A.

FIG. 4C is a cross-sectional view taken along line B-B of FIG. 4A.

FIG. 5A is a plan view illustrating the method for manufacturing the semiconductor optical device.

FIG. 5B is a cross-sectional view taken along line A-A of FIG. 5A.

FIG. 5C is a cross-sectional view taken along line B-B of FIG. 5A.

FIG. 6A is a plan view illustrating the method for manufacturing the semiconductor optical device.

FIG. 6B is a cross-sectional view taken along line A-A of FIG. 6A.

FIG. 6C is a cross-sectional view taken along line B-B of FIG. 6A.

FIG. 7A is a plan view illustrating the method for manufacturing the semiconductor optical device.

FIG. 7B is a cross-sectional view taken along line A-A of FIG. 7A.

FIG. 7C is a cross-sectional view taken along line B-B of FIG. 7A.

FIG. 8A is a plan view illustrating the method for manufacturing the semiconductor optical device.

FIG. 8B is a cross-sectional view taken along line A-A of FIG. 8A.

FIG. 9 is a cross-sectional view illustrating a semiconductor optical device according to a comparative example.

FIG. 10 is a cross-sectional view illustrating a semiconductor optical device according to a modification.

FIG. 11A is a cross-sectional view illustrating a semiconductor optical device according to a second embodiment.

FIG. 11B is a cross-sectional view illustrating a substrate.

FIG. 12 is a graph illustrating an example of an optical confinement coefficient and heat dissipation.

FIG. 13A is a cross-sectional view illustrating a semiconductor optical device according to a third embodiment.

FIG. 13B is a cross-sectional view illustrating a substrate.

### DETAILED DESCRIPTION

Light is generated when current is injected to a semiconductor element. Heat is generated as the semiconductor element operates, and it is desirable to increase heat dissipation in order to prevent degradation of characteristics due to temperature rise. On the other hand, it is important to increase an optical confinement to the semiconductor element in order to obtain good characteristics. However, it is difficult to achieve both the heat dissipation and the optical confinement. It is therefore an object of the present disclosure to provide a semiconductor optical device and a method for manufacturing a semiconductor optical device that can achieve both the heat dissipation and the optical confinement.

First, the contents of the embodiments of this disclosure are listed and explained.

(1) A semiconductor optical device according to the present disclosure includes a substrate containing silicon, and a semiconductor element bonded to the substrate, formed of a compound semiconductor and having an optical gain. The substrate includes a waveguide and a first region connected to the waveguide in an extension direction of the waveguide. The first region includes a plurality of recesses and a plurality of protrusions. Each of the plurality of recesses is recessed in a thickness direction of the substrate compared to a surface of the substrate to which the semiconductor element is bonded. Each of the plurality of protrusions protrudes in the thickness direction of the substrate from bottom surfaces of the plurality of recesses. The plurality of recesses and the plurality of protrusions are alternately disposed in a direction intersecting with the extension direction of the waveguide. The semiconductor element is bonded to the first region. Since the plurality of protrusions are provided, heat dissipation can be enhanced. Since the plurality of recesses are provided, an effective refractive index of the waveguide of the substrate is reduced, and an optical confinement can be increased. It is possible to achieve both the heat dissipation and the optical confinement.

(2) The substrate may include a silicon layer. The waveguide, the plurality of protrusions, and the plurality of recesses may be provided in the silicon layer. Since the plurality of protrusions made of silicon are provided, heat is easily dissipated through the silicon layer, and the heat dissipation can be enhanced. Since the recess is a portion in which the silicon is lost, the effective refractive index of the waveguide made of the silicon layer decreases, and the optical confinement can be increased.
(3) The substrate may include a second region and a groove. The groove may be located on either of both sides of the waveguide in the direction intersecting with the extension direction of the waveguide. The second region may be located on a side opposite to the waveguide with respect to the groove. The first region may be connected to the second region in the direction intersecting with the extension direction of the waveguide. The semiconductor element may be bonded to the first region and the second region. Grooves are not provided on both sides of the first region. An amount of air under the semiconductor element is reduced compared to a case where there is a groove. Reducing the amount of air having low thermal conductivity increases the heat dissipation.
(4) The semiconductor element may be in contact with upper surfaces of the plurality of protrusions and an upper surface of the second region. Since heat is easily transferred to the protrusions and the second region, the heat dissipation is further improved.
(5) The semiconductor element may include a first cladding layer having a first conductive type, an active layer, and a second cladding layer having a second conductive type. The first cladding layer, the active layer, and the second cladding layer may be stacked in this order from a side close to the substrate side. The semiconductor element may include a mesa. The mesa may be located on the first region, protrude from the side closer the substrate side toward a side opposite to the substrate, include the second cladding layer. The semiconductor optical device may further include a first electrode electrically connected to the first cladding layer, and a second electrode electrically connected to the second cladding layer of the mesa. Since the semiconductor element has the mesa, the optical confinement of the active layer can be further enhanced. Since the first region is located below the mesa which serves as a heat source, heat is effectively dissipated.
(6) A width of the first region in the direction intersecting with the extension direction of the waveguide may be larger than a width of the mesa. Since the first region is located entirely under the mesa serving as the heat source, heat is effectively dissipated.
(7) The plurality of protrusions may include a first protrusion located at a center in the direction intersecting with the extension direction of the waveguide, the first protrusion being located under the mesa. Heat is efficiently dissipated from the mesa through the first protrusion. The heat dissipation is further improved.
(8) A width of the first protrusion may be larger than widths of the protrusions other than the first protrusion. Heat is efficiently dissipated from the mesa through the first protrusion. The heat dissipation is further improved.
(9) The plurality of protrusions may have larger widths as the plurality of protrusions are located closer to a center of the mesa. Heat is efficiently dissipated from the mesa. The heat dissipation is further improved.
(10) The plurality of recesses may be disposed symmetrically with respect to the mesa in the direction intersecting with the extension direction of the waveguide. The plurality of protrusions may be disposed symmetrically with respect to the mesa in the direction intersecting with the extension direction of the waveguide. A distribution of light becomes also symmetrical and shapes of optical modes becomes stable.
(11) The first region may include a tapered portion. The tapered portion may be tapered from the first region toward the waveguide in the extension direction of the waveguide. The waveguide may be connected to a distal end of the tapered portion. End portions of the recess and end portions of the protrusion in the extension direction of the waveguide may be located in the tapered portion. Toward the distal end of the tapered portion, the effective refractive index of the waveguide of the substrate changes continuously. The optical mode is stabilized.
(12) A method for manufacturing a semiconductor optical device according to the present disclosure includes a step of preparing a substrate containing silicon, and a step of bonding a semiconductor element formed of a compound semiconductor and having an optical gain to the substrate. The substrate includes a waveguide and a first region connected to the waveguide in an extension direction of the waveguide. The first region includes a plurality of recesses and a plurality of protrusions. Each of the plurality of recesses is recessed in a thickness direction of the substrate compared to a surface of the substrate to which the semiconductor element is bonded. Each of the plurality of protrusions protrudes in the thickness direction of the substrate compared to bottom surfaces of the plurality of recesses. The plurality of recesses and the plurality of protrusions are alternately disposed in a direction intersecting with the extension direction of the waveguide. The semiconductor element is bonded to the first region in the step of bonding the semiconductor element to the substrate. Since the plurality of protrusions are provided, heat dissipation can be enhanced. Since the plurality of recesses are provided, an effective refractive index of the substrate is reduced, and an optical confinement can be increased. It is possible to achieve both the heat dissipation and the optical confinement.

### DETAILED DESCRIPTION OF EMBODIMENTS OF THE DISCLOSURE

Specific examples of semiconductor optical devices and methods for manufacturing thereof in accordance with embodiments of the present disclosure are described below with reference to the drawings. The present disclosure is not limited to these examples, but is indicated by the claims, which are intended to include all modifications within the meaning and scope of the claims.

### First Embodiment

### Semiconductor Optical Device

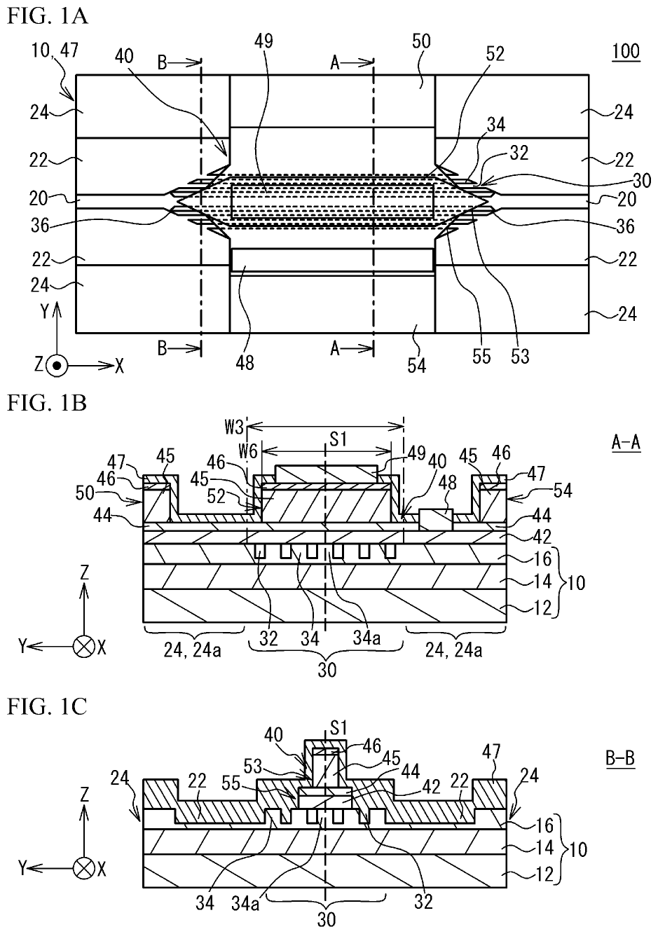

FIG. 1A is a plan view illustrating a semiconductor optical device 100 according to a first embodiment. FIG. 1B is a cross-sectional view taken along line A-A of FIG. 1A. FIG. 1C is a cross-sectional view taken along line B-B of FIG. 1A. Semiconductor optical device 100 has edges extending in an X-axis direction and edges extending in a Y-axis direction. A Z-axis direction is a stacking direction of layers. The X-axis, Y-axis, and Z-axis directions are orthogonal to each other. As illustrated in FIG. 1A to FIG. 1C, semiconductor optical device 100 is a hybrid laser device having a substrate 10 and a semiconductor element.

### Substrate

As illustrated in FIG. 1B and FIG. 1C, substrate 10 is an SOI substrate having a silicon (Si) substrate 12, a silicon dioxide (SiO₂) layer 14, and an Si layer 16 stacked in this order in the Z-axis direction.

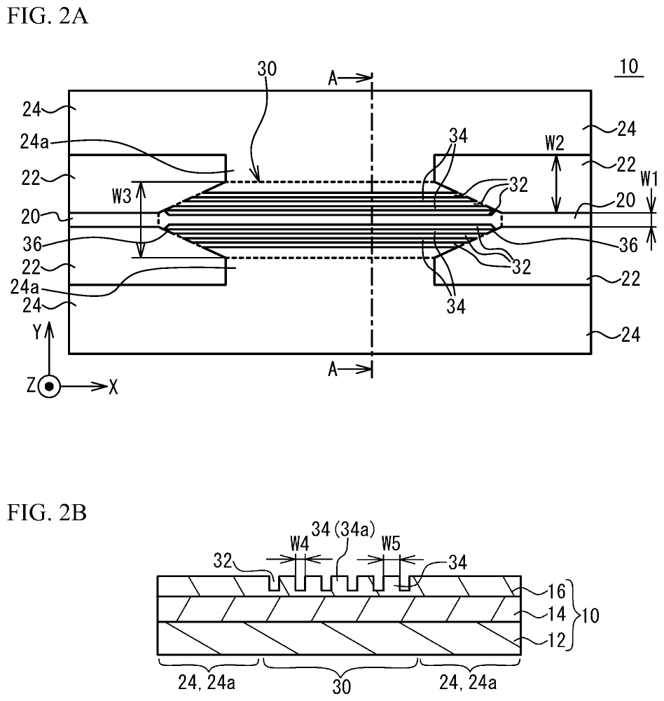

FIG. 2A is a plan view illustrating substrate 10. FIG. 2B is a cross-sectional view taken along line A-A in FIG. 2A. In Si layer 16 of substrate 10, two waveguides 20, four grooves 22, a first region 30, and two second regions 24 are provided.

Waveguide 20 extends in the X-axis direction. The X-axis direction is an extension direction of waveguide 20. Grooves 22 are located on both sides of each waveguide 20 in the Y-axis direction. The Y-axis direction is a direction intersecting with (e.g., orthogonal to) the extension direction of waveguide 20. Each waveguide 20 is disposed between two grooves 22. Second region 24 is provided opposite to waveguide 20 with respect to groove 22 in the Y-axis direction. Groove 22 is located between waveguide 20 and second region 24.

Second region 24 is a terrace of Si layer 16, and has a surface of Si. First region 30 is disposed between two second regions 24 in the Y-axis direction. A portion of second region 24 facing first region 30 is a protruding portion 24a. Protruding portion 24a protrudes in the Y-axis direction toward first region 30 and is connected to first region 30. Groove 22 is not provided between first region 30 and second region 24.

One end of each of two waveguides 20 is located at an end portion of substrate 10, and the other end is connected to first region 30. Waveguide 20, first region 30, and waveguide 20 are lined up in this order from one end portion to the other end portion of substrate 10 in the X-axis direction.

Tapered portions 36 are provided at both ends of first region 30 in the X-axis direction. Each tapered portion 36 is tapered from a side close to first region 30 toward a side close to waveguide 20 in the X-axis direction. Waveguide 20 is connected to a distal end of tapered portion 36.

First region 30 includes a plurality of recesses 32 and a plurality of protrusions 34. As illustrated in FIG. 2A, recesses 32 and protrusions 34 extend in the X-axis direction. In the Y-axis direction, each of the plurality of recesses 32 and each of the plurality of protrusions 34 are alternately disposed. In other words, one recess 32 is located on both sides of one protrusion 34.

As illustrated in FIG. 1B, FIG. 1C, and FIG. 2B, first region 30 has, for example, six recesses 32 and five protrusions 34. The numbers of recesses 32 and protrusions 34 may be changed. Among the multiple protrusions 34, the one located at the center in the Y-axis direction is designated as a protrusion 34a (first protrusion).

A width W1 of waveguide 20 in the Y-axis direction illustrated in FIG. 2A is, for example, 0.5 μm. A width W2 of groove 22 is, for example, 5 μm. A width W3 of first region 30 in the Y-axis direction is, for example, 5 μm. In the first embodiment, widths of the plurality of recesses 32 are equal to each other. Widths of the plurality of protrusions 34 are equal to each other. Each width W4 of recesses 32 illustrated in FIG. 2B is, for example, 0.3 μm. Each width W5 of protrusions 34 is, for example, 0.3 μm. The width W4 may be equal to or different from the width W5.

As illustrated in FIG. 2A, recess 32 and protrusion 34 extend up to tapered portion 36 in the X-axis direction. An end portion of recess 32 in the X-axis direction and an end portion of protrusion 34 in the X-axis direction are located at tapered portion 36.

As illustrated in FIG. 1B, FIG. 1C, and FIG. 2B, an upper surface of waveguide 20, upper surfaces of protrusions 34 in first region 30, and upper surfaces of second regions 24 are located at the same height from substrate 12 in the Z-axis direction (thickness direction of substrate 10) and in a same plane. The upper surface of protrusion 34 protrudes in the Z-axis direction compared to a bottom surface of recess 32. The bottom surface of recess 32 is recessed in the Z-axis direction compared to the upper surface of waveguide 20 of substrate 10. A bottom surface of groove 22 and the bottom surface of recess 32 are located at the same height from substrate 12 in the Z-axis direction and in a same plane. Depths of groove 22 and recess 32 are smaller than a thickness of Si layer 16. That is, groove 22 and recess 32 do not penetrate through Si layer 16 in the Z-axis direction. For example, Si layer 16 with a thickness of about 30 nm is located below the bottom surfaces of groove 22 and recess 32.

### Semiconductor Element

As illustrated in FIG. 1A to FIG. 1B, a semiconductor element 40 is bonded on first region 30 and two second regions 24 of substrate 10. Semiconductor element 40 is a light-emitting device having a ridge mesa structure formed of III-V compound semiconductors. As illustrated in FIG. 1B and FIG. 1C, semiconductor element 40 has a cladding layer 42 (first cladding layer), an active layer 44, a cladding layer 45 (second cladding layer), and a contact layer 46 stacked in this order in the Z-axis direction from a side close to substrate 10.

Cladding layer 42 is formed, for example, of n-type indium phosphide (n-InP). Cladding layer 45 is formed, for example, of p-InP. Contact layer 46 is formed, for example, of p-type indium gallium arsenide (p-InGaAs). Active layer 44 includes, for example, a plurality of alternately stacked well layers and barrier layers, and has a multiple quantum well (MQW) structure. The well layer and the barrier layer are formed of, for example, undoped gallium indium arsenide phosphide (i-GaInAsP). Spacer layers may be provided between active layer 44 and cladding layer 42 and between active layer 44 and cladding layer 45. Semiconductor element 40 may be formed of a compound semiconductor other than those described above.

Semiconductor element 40 includes three mesas 50, 52, and 54. Mesas 50, 52, and 54 are disposed in order in the Y-axis direction and separated from each other. Mesa 50 is located on one of the two second regions 24. Mesa 54 is located on the other of the two second regions 24. Mesa 52 is located on first region 30. As illustrated in FIG. 1B and FIG. 1C, mesas 50, 52, and 54 are formed of cladding layer 45 and contact layer 46, and protrude in the opposite direction (upward in the Z-axis) from substrate 10. Cladding layer 42 and active layer 44 extend from mesa 50 to mesa 54.

A width W6 of mesa 52 illustrated in FIG. 1B is, for example, 3 which is smaller than the width W3 of first region 30. The plurality of recesses 32 and the plurality of protrusions 34 are located under mesa 52. In FIG. 1B and FIG. 1C, a line segment S1 is illustrated by a dashed line, which is a virtual line extending in the Z-axis direction and passing through the center of mesa 52 in the Y-axis direction. Protrusion 34a is located under mesa 52 and overlaps the line segment S1.

In the Y-axis direction, the plurality of recesses 32 are symmetrically arranged with respect to mesa 52. The plurality of protrusions 34 are symmetrically arranged with respect to mesa 52. More precisely, the plurality of recesses 32 and the plurality of protrusions 34 are disposed in line symmetry with respect to the line segment S1. In other words, the number of recesses 32 arranged on one side of the Y-axis direction with respect to the line segment S1 is equal to the number of recesses 32 arranged on the opposite side. The number of protrusion 34 on one side of the Y-axis direction with respect to the line segment S1 is equal to the number of protrusion 34 on the opposite side.

As illustrated in FIG. 1A, lengths along the X-axis direction of mesas 50, 52, and 54 are smaller than a length of first region 30, for example. The length along the X-axis direction of mesa 52 is larger than the lengths along the X-axis direction of mesas 50 and 54. Mesa 52 has two tapered portions 53 at end portions in the X-axis direction. Tapered portion 53 protrudes in the X-axis direction and tapers from semiconductor element 40 toward waveguide 20.

As illustrated in FIG. 1A, cladding layer 42 and active layer 44 form two tapered portions 55. Tapered portion 55 is located on tapered portion 36 of substrate 10, protrudes in the X-axis direction, and tapers from semiconductor element 40 toward waveguide 20. As illustrated in FIG. 1B and FIG. 1C, tapered portion 53 is located on tapered portion 55. In a distal end of tapered portion 53, tapered portion 53 merges into tapered portion 55. Tapered portions 53 and 55 are shorter than tapered portion 36 of substrate 10. In other words, tapered portion 36 protrudes further toward waveguide 20 than tapered portions 53 and 55.

As illustrated in FIG. 1B to FIG. 1C, an insulating film 47 is a cladding layer made of, for example, silicon dioxide (SiO₂). Insulating film 47 covers upper surfaces and side surfaces of mesas 50, 52 and 54, covers an upper surface of active layer 44 between the mesas, and also covers an upper surface of substrate 10.

As illustrated in FIG. 1B, an electrode 48 is an n-type electrode provided between mesa 52 and mesa 54, and is electrically connected to cladding layer 42 through an opening in insulating film 47. Electrode 48 has an ohmic electrode and a wiring layer. The ohmic electrode is formed, for example, of an alloy of gold, germanium and nickel (AuGeNi). The wiring layer is formed of, for example, Au. An electrode 49 is a p-type electrode provided on the upper surface of mesa 52, and is electrically connected to contact layer 46 through an opening in insulating film 47. Electrode 49 has an ohmic electrode and a wiring layer. The ohmic electrode is formed, for example, of a laminated body of titanium, platinum and gold (Ti/Pt/Au). The wiring layer is formed of Au, for example.

Active layer 44 of the semiconductor element 40 has an optical gain. Voltage is applied between electrodes 48 and 49, and current flows between the electrodes. Current flows through mesa 52, active layer 44, and cladding layer 42. By injecting carriers into active layer 44 under mesa 52, active layer 44 emits light. Semiconductor element 40 and substrate 10 are evanescently optically coupled. The light generated in semiconductor element 40 transitions to substrate 10, propagates through waveguide 20, and is emitted out of semiconductor optical device 100.

Since grooves 22 are provided on both sides of waveguide 20, light can be strongly confined in waveguide 20 due to a difference of refractive indexes between Si of waveguide 20 and the air in grooves 22. On the other hand, there is no groove 22 on both sides of first region 30. The semiconductor element 40 of ridge mesa structure has mesa 52 on first region 30. The ridge mesa structure and a recessed/projecting structure with recess 32 and protrusion 34 reduce an effective refractive index. The reduction of the effective refractive index allows for controlling of modes of the light since the light is strongly confined to active layer 44 and is less likely to spread to Si layer 16 of substrate 10.

During the operation of semiconductor optical device 100, mesa 52, active layer 44 and cladding layer 42 become the pathway of the current and generate heat. As illustrated in FIG. 1B and FIG. 1C, substrate 10 has SiO₂ layer 14, and semiconductor element 40 is covered with SiO₂ insulating film 47. The heat generated in the semiconductor element 40 does not escape easily in the vertical direction and is dissipated in the XY plane through, for example, Si layer 16 and cladding layer 42.

In order to suppress deterioration of characteristics due to temperature rise, it is important to increase heat dissipation. As illustrated in FIG. 1A to FIG. 2B, first region 30 of substrate 10 has the plurality of protrusions 34. The heat generated in semiconductor element 40 is transferred to Si layer 16 through protrusion 34 and is dissipated. Therefore, heat dissipation can be increased. On the other hand, since first region 30 has the plurality of recesses 32, the effective refractive index of Si layer 16 is lower than that in the case where there is no recess 32, for example. The leakage of light into substrate 10 is suppressed and the light can be strongly confined in active layer 44. As described above, it is possible to achieve both high heat dissipation and high optical confinement.

### Method for Manufacturing

For manufacturing semiconductor optical device 100, a wafer of SOI substrate (substrate 10) and a wafer of III-V compound semiconductor to fabricate semiconductor element 40 are used.

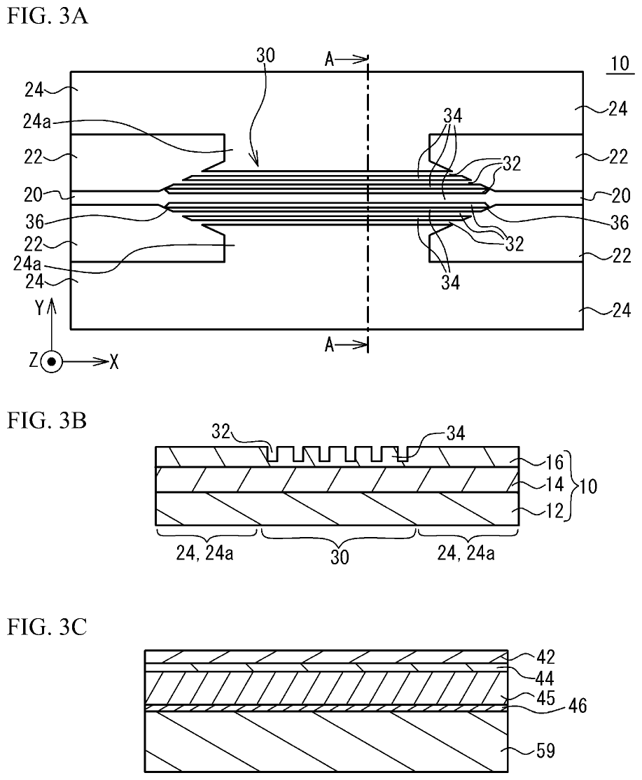

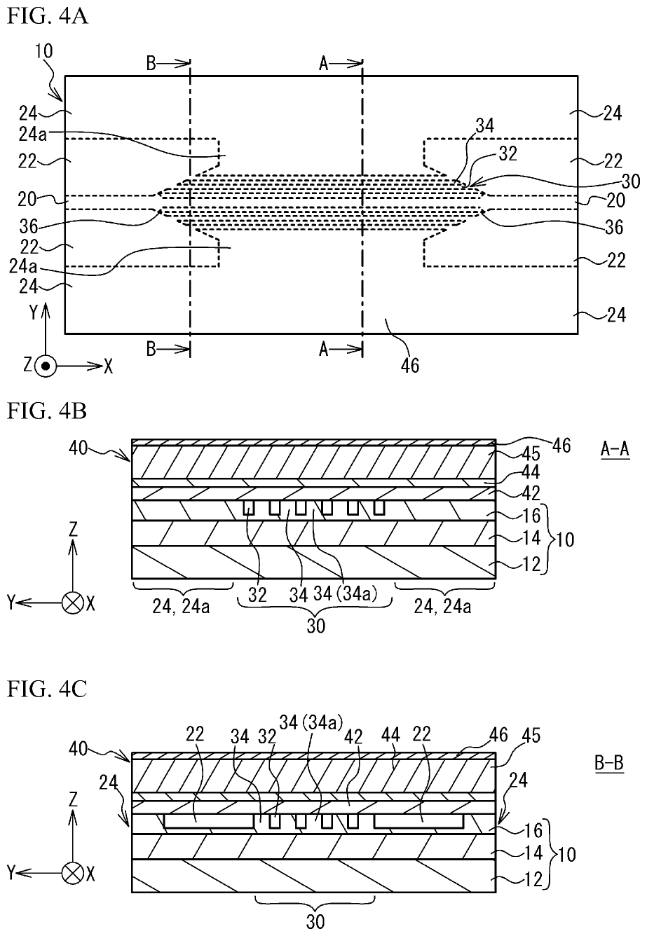

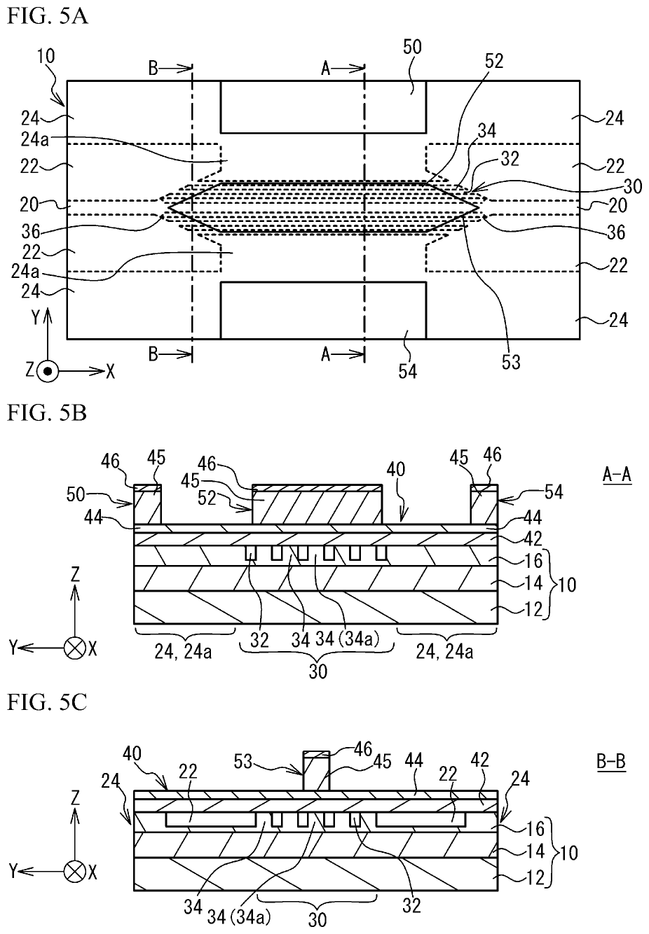

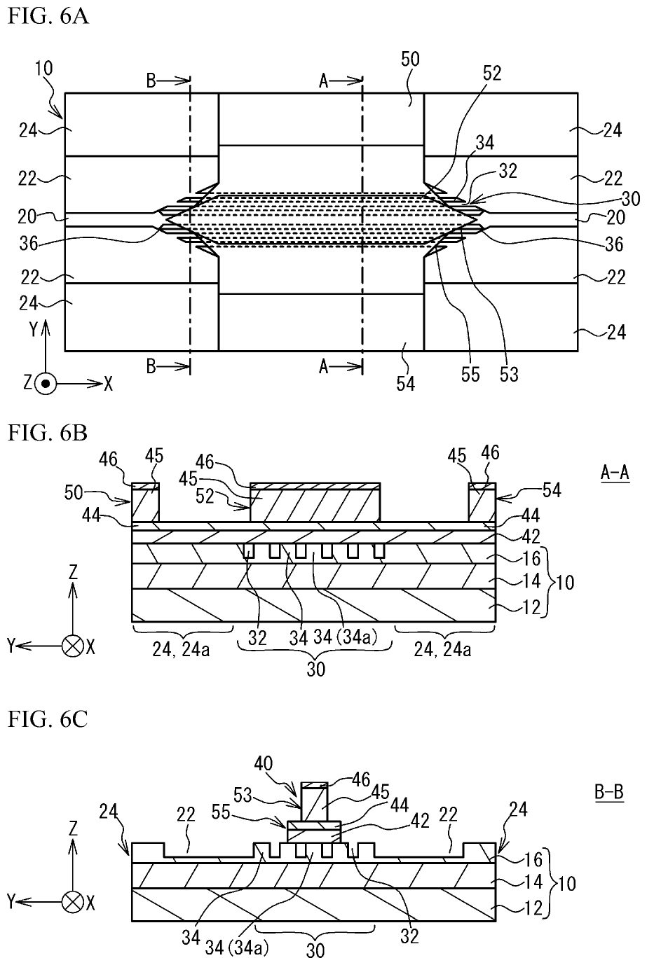

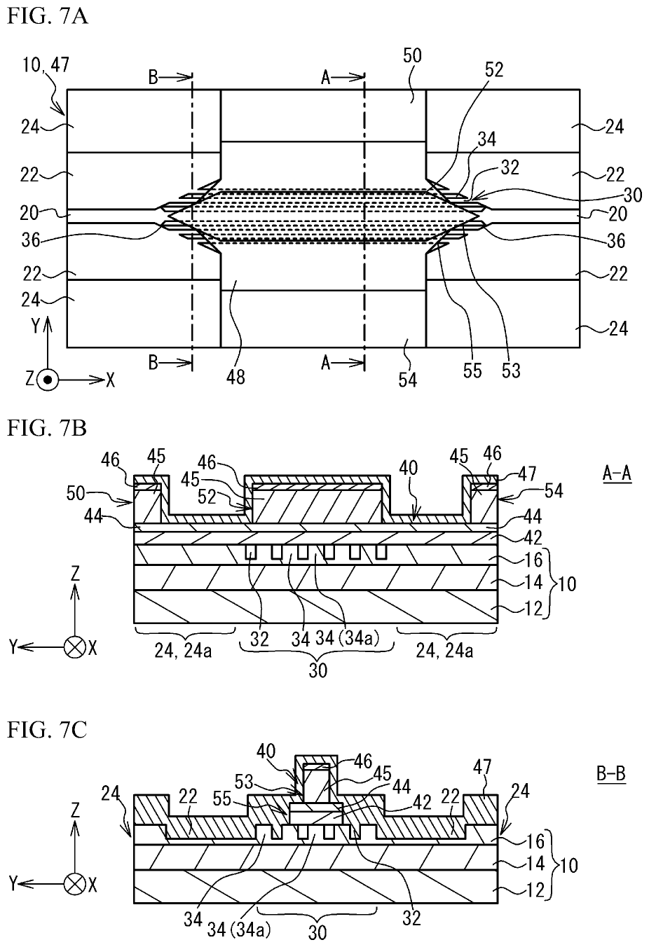

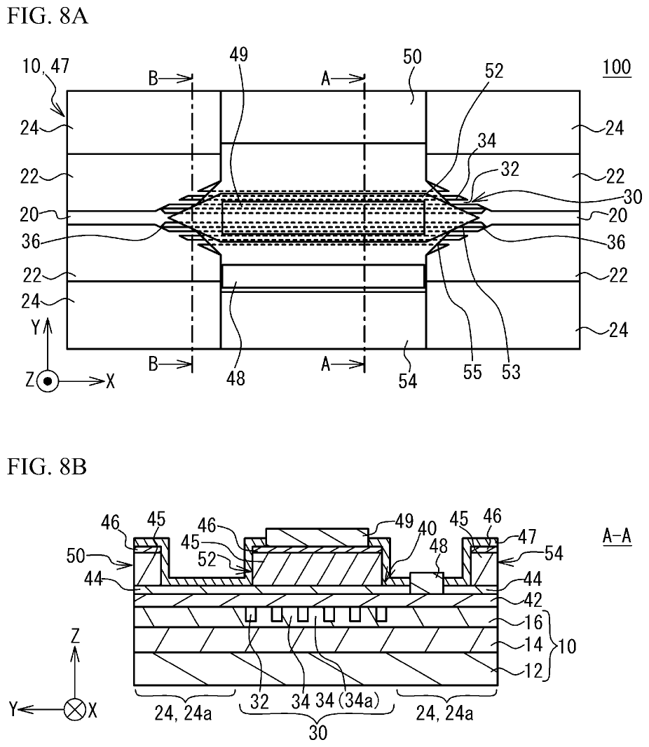

FIG. 3A, FIG. 4A, FIG. 5A, FIG. 6A, FIG. 7A, and FIG. 8A are plan views illustrating a method for manufacturing semiconductor optical device 100. FIG. 3B, FIG. 4B, FIG. 5B, FIG. 6B, and FIG. 7B are cross-sectional views taken along line A-A of the corresponding plan views. FIG. 4C, FIG. 5C, FIG. 6C, and FIG. 7C are cross-sectional views taken along line B-B of the corresponding plan views. FIG. 3C is a cross-sectional view illustrating the method for manufacturing of semiconductor optical device 100, and illustrates the fabrication of a semiconductor element 40.

First, substrate 10 is prepared. Substrate 10 in a wafer state has multiple regions in which semiconductor optical device 100 is formed. In each of these regions of substrate 10, waveguides 20, grooves 22, second regions 24, recesses 32, protrusions 34 and tapered portions 36 are formed as illustrated in FIG. 3A and FIG. 3B. For example, a resist pattern is formed on the upper surface of substrate 10 by electron beam lithography, and dry etching is performed on Si layer 16 of substrate 10. Grooves 22 and recesses 32 are formed in the dry-etched region, and waveguides 20, second regions 24, protrusions 34, and tapered portions 36 are formed in the non-dry-etched region.

FIG. 3C is a cross-sectional view illustrating the method for manufacturing of semiconductor element 40. For example, contact layer 46, cladding layer 45, active layer 44, and cladding layer 42 are epitaxially grown in this order on an upper surface of an InP substrate 59 by OMVPE (Organometallic Vapor Phase Epitaxy). Cladding layer 42 is exposed on a surface. Dicing is performed on InP substrate 59 to form multiple semiconductor elements 40. At the time of dicing, mesas 50, 52 and 54, electrodes, and tapered portion 53 and 55 are not formed on semiconductor element 40.

FIG. 4A to FIG. 8B illustrate a step of bonding of the semiconductor element 40 to the substrate 10, and steps after the bonding. The surface of cladding layer 42 of semiconductor element 40 and the surface of Si layer 16 of substrate 10 are activated by plasma irradiation or the like. As illustrated in FIG. 4A to 4C, semiconductor element 40 is bonded to upper surfaces of first region 30, waveguides 20, and two second regions 24 of substrate 10. No adhesive such as resin is used and cladding layer 42 is brought into contact with the upper surface of Si layer 16. The plurality of recesses 32 and protrusions 34 are located under semiconductor element 40.

After bonding, wet etching is used to remove substrate 59 of semiconductor element 40 to expose a surface of contact layer 46. Etchant flows into grooves 22 of substrate 10, but is stopped by second regions 24, and etching from a lower surface (cladding layer 42) of semiconductor element 40 is suppressed.

As illustrated in FIG. 5A to 5C, mesas 50, 52 and 54 are formed on semiconductor element 40. More specifically, a mask material such as SiO₂ is deposited on the surfaces of substrate 10 and semiconductor element 40, and a resist pattern is formed by photolithography. Dry etching is performed using the resist mask (not illustrated) to form the SiO₂ mask. After that, dry etching is performed using the SiO₂ mask. Portions of contact layer 46 and cladding layer 45 that are not covered by the SiO₂ mask are removed, and portions that are covered are left. Mesas 50, 52 and 54 are formed by the dry etching described above. Mesa 52 has tapered portions 53. As illustrated in FIG. 5B and FIG. 5C, protrusion 34a is located under the center of mesa 52 in the Y-axis direction. After the etching, the SiO₂ mask is removed.

As illustrated in FIG. 6A to FIG. 6C, tapered portions 55 are formed on semiconductor element 40. An SiO₂ is deposited on semiconductor element 40, and an SiO₂ mask (not illustrated) is formed by photolithography and dry etching. Mesas 50, 52 and 54 are covered with the SiO₂ mask. Portions of active layer 44 between mesa 50 and mesa 52 and between mesa 52 and mesa 54 are covered with the SiO₂ mask, and other portions of active layer 44 are exposed from the SiO₂ mask. Portions of semiconductor element 40 exposed from the SiO₂ mask is dry etched to remove a part of active layer 44 and a part of cladding layer 42, thereby forming tapered portions 55 and exposing the upper surface of substrate 10. Active layer 44 and cladding layer 42 spread from under mesa 50 to under mesa 54. After the etching, the SiO₂ mask is removed.

As illustrated in FIG. 7A to FIG. 7C, insulating film 47 is formed on the upper surface of substrate 10 and the surface of semiconductor element 40 by, for example, Chemical Vapor Deposition (CVD). Insulating film 47 covers the upper surfaces and the side surfaces of mesas 50, 52, and 54, respectively, and the upper surface of active layer 44. As illustrated in FIG. 8A and FIG. 8B, openings are provided in insulating film 47 on mesa 52 and between mesa 52 and mesa 54, and electrodes 48 and 49 are provided in the openings by, for example, vacuum deposition. The cross section along the line B-B is the same as that in FIG. 7C. By the above steps, semiconductor optical device 100 is formed.

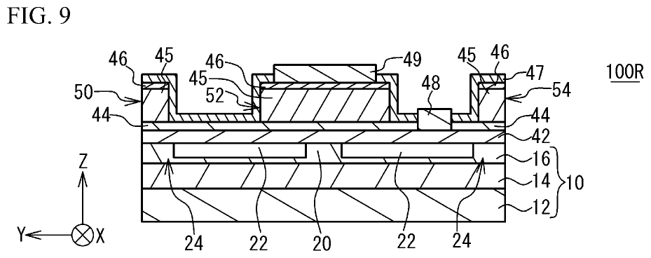

FIG. 9 illustrates a cross-sectional view illustrating a semiconductor optical device 100R according to a comparative example, and illustrates a cross section corresponding to FIG. 1B. Substrate 10 of the comparative example does not have recess 32 and protrusion 34. Waveguide 20 and two grooves 22 extend from outside of semiconductor element 40 to under semiconductor element 40. Waveguide 20 is located under mesa 52 of semiconductor element 40. Grooves 22 are provided on both sides of the waveguide 20 in the Y-axis direction. One groove 22 is located from under mesa 52 to a vicinity of mesa 50. The other groove 22 is positioned from under mesa 52 to a vicinity of the mesa 54.

Groove 22 is hollow and the inside is filled with air. The thermal conductivity of air is lower than that of Si, so the heat generated in semiconductor element 40 by the operation of semiconductor optical device 100R is less likely to be dissipated to Si layer 16. Semiconductor element 40 is covered with insulating film 47. Substrate 10 has SiO₂ layer 14 under silicon layer 16. Heat is also less likely to be dissipated in the Z-axis direction. Since heat is less likely to escape, the temperature is likely to rise, and the characteristics are likely to deteriorate due to the temperature rise.

According to the first embodiment, first region 30 of substrate 10 has the plurality of recesses 32 and the plurality of protrusions 34. The plurality of recesses 32 and plurality of protrusions 34 are provided in Si layer 16, and located under semiconductor element 40. Each recess 32 and each protrusion 34 are alternately aligned in the Y-axis direction. Protrusion 34 made of Si has a higher thermal conductivity than air. For example, heat is more easily transferred from semiconductor element 40 to Si layer 16 compared with the case where grooves 22 are provided under semiconductor element 40, resulting in higher heat dissipation.

Recess 32 is a portion of Si layer 16 where Si is lost. Since recess 32 is provided in Si layer 16, the effective refractive index of Si layer 16 is reduced as compared with the case where recess 32 is not provided. Thus, optical confinement to active layer 44 under mesa 52 becomes strong. As described above, according to first embodiment, both heat dissipation and optical confinement can be achieved. By increasing the heat dissipation, deterioration of characteristics due to the temperature rise is suppressed. An optical confinement coefficient to active layer 44 on first region 30 can be increased to, for example, 5% or more.

Si layer 16 of substrate 10 has waveguide 20, groove 22 and second region 24. Groove 22 is covered with, for example, insulating film 47. Due to a difference of refractive indexes between waveguide 20 of Si and insulating film 47, the optical confinement to waveguide 20 can be enhanced. First region 30 is connected to two second regions 24 on both sides in the Y-axis direction, and no groove 22 is provided on both sides of first region 30. An amount of air under semiconductor element 40 is reduced as compared with the case where groove 22 is provided. Reducing the amount of air which has a low thermal conductivity increases heat dissipation. In the comparative example, in order to stabilize the mode of light, a total width of two grooves 22 is set to, for example, 4 μm or more. In the first embodiment, a total width of the six recesses 32 is, for example, 1.8 μm, which is equal to or less than a half of the total width of grooves 22. By reducing the amount of air to half or less, heat dissipation is improved.

An adhesive can be provided between semiconductor element 40 and Si layer 16 of substrate 10. However, it is preferable to bring semiconductor element 40 in contact with Si layer 16 and not use an adhesive. Since protrusions 34 of the substrate 10 are in contact with semiconductor element 40, a contact area between substrate 10 and semiconductor element 40 is increased. Heat dissipation is improved and bonding strength is also increased. The upper surface of the protrusion 34 and the upper surface of the second region 24 are located at the same height and form the same plane. As semiconductor element 40 is in contact with the upper surface of the protrusion 34 and the upper surface of second region 24, the contact area is further increased. Effective improvements in heat dissipation and bonding strength are possible. The bottom surface of recess 32 may be SiO₂ layer 14, but it is preferable to be Si layer 16. A depth of recess 32 should be smaller than a thickness of Si layer 16, so that heat can be transferred through Si layer 16 more easily.

Substrate 10 may be SOI substrate or any substrate other than the SOI substrate. Substrate 10 is preferably substrate containing Si. A difference of refractive indexes between substrate 10 and semiconductor element 40 can enhance the optical confinement to active layer 44. A difference of refractive indexes between substrate 10 and insulating film 47 can enhance the optical confinement to waveguide 20. Recess 32 and protrusion 34 may be provided on the surface of substrate 10 to which semiconductor element 40 is bonded.

Semiconductor element 40 has the ridge mesa structure and has mesa 52. Mesa 52 is formed of cladding layer 45 and contact layer 46. Active layer 44 and cladding layer 42 are located under mesa 52. The ridge mesa structure allows light to be confined in active layer 44.

As described above, current is input to mesa 52, and active layer 44 under mesa 52 generates light. Mesa 52 and its vicinity in semiconductor element 40 are prone to heat generation. The width W3 of first region 30 of substrate 10 is preferably larger than the width W1 of mesa 52. That is, as illustrated in FIG. 1B, the plurality of recesses 32 and the plurality of protrusions 34 extend from under one end of mesa 52 to under the other end thereof in the Y-axis direction. Heat is easily dissipated from semiconductor element 40 to substrate 10. The optical confinement is also kept strong. The width W3 may be, for example, 1.5 times or more, or 2 times or more than the width W1.

As illustrated in FIG. 1B and FIG. 1C, protrusion 34a of the plurality of protrusions 34 is located under mesa 52. As described above, mesa 52 becomes a heat source when semiconductor optical device 100 is driven. By protrusion 34a being disposed just under mesa 52, heat is smoothly dissipated from mesa 52 to Si layer 16 through protrusion 34a. In particular, heat dissipation is further improved by locating protrusion 34a under the center of mesa 52 illustrated by line segment S1.

In the Y-axis direction, the plurality of recesses 32 are symmetrically arranged with respect to mesa 52. The plurality of protrusions 34 are also arranged symmetrically with respect to mesa 52. More preferably, with respect to line segment S1 passing through the center of mesa 52, the arrangement of recesses 32 is symmetrical, and the arrangement of protrusions 34 is symmetrical. With respect to both sides of line segment S1 in the Y-axis direction, the number of recesses 32 on one side is equal to the number of recesses 32 on the other side. With respect to both sides of line segment S1 in the Y-axis direction, the number of protrusions 34 located on one side is equal to the number of protrusions 34 located on the opposite side. With respect to both sides of line segment S1 in the Y-axis direction, the total width of recesses 32 on one side is equal to the total width of recesses 32 on the opposite side. With respect to both sides of line segment S1 in the Y-axis direction, the total width of protrusions 34 on one side is equal to the total width of protrusions 34 on the opposite side. Mode shape is stable because the light is symmetrically distributed with respect to mesa 52.

Each width of the plurality of recesses 32 may be equal to or different from each other. However, it is preferable that the arrangement of recesses 32 is symmetrical about mesa 52 as described above. In the first embodiment, the width of each of the plurality of protrusions 34 is equal to each other. As described in the second and third embodiments, each width of the plurality of protrusions 34 may be different.

As illustrated in FIG. 1A and FIG. 2A, Si layer 16 of substrate 10 has tapered portions 36. Tapered portion 36 tapers from the vicinity of first region 30 to the opposite side of first region 30. Tapered portion 36 can suppress a loss of light between first region 30 and waveguide 20. An end portion of recess 32 in the X-axis direction and an end portion of protrusion 34 in the X-axis direction are located in tapered portion 36. As the width of first region 30 decreases, the number of recesses 32 and the number of protrusions 34 also decrease. At a position of the line A-A in FIG. 1A, the number of recesses 32 is six and the number of protrusions 34 is five. At a position of the line B-B across tapered portion 36, the number of recesses 32 is four. As the distal end of tapered portion 36 is approached, recesses 32 and protrusions 34 become even less. Toward the distal end of tapered portion 36, the effective refractive index of substrate 10 changes continuously. Compared with the case where the refractive index changes discontinuously, the mode of light is stabilized.

As illustrated in FIG. 1A, semiconductor element 40 has tapered portions 53 and 55 each tapered from first region 30 toward waveguide 20. This strengthens the optical coupling between semiconductor element 40 and waveguide 20 and suppresses the loss of light.

### Modification

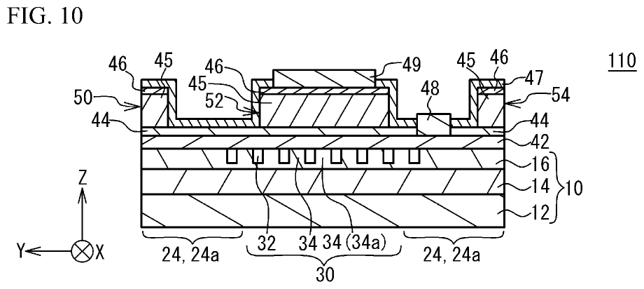

FIG. 10 is a cross-sectional view illustrating a semiconductor optical device 110 according to a modification, and illustrates a cross section corresponding to FIG. 1B. Description of the same configuration as in the first embodiment will be omitted. As illustrated in FIG. 10, first region 30 has eight recesses 32 and seven protrusions 34. The two recesses 32 located outermost in the Y-axis direction among the eight recesses 32 do not overlap with mesa 52 of semiconductor element 40.

As illustrated in FIG. 10, the number of recesses 32 and the number of protrusions 34 may be modified from the example in FIG. 1B. The plurality of recesses 32 and the plurality of protrusions 34 are placed from a position overlapping mesa 52 to outside mesa 52. Heat dissipation and optical confinement can be improved.

### Second Embodiment

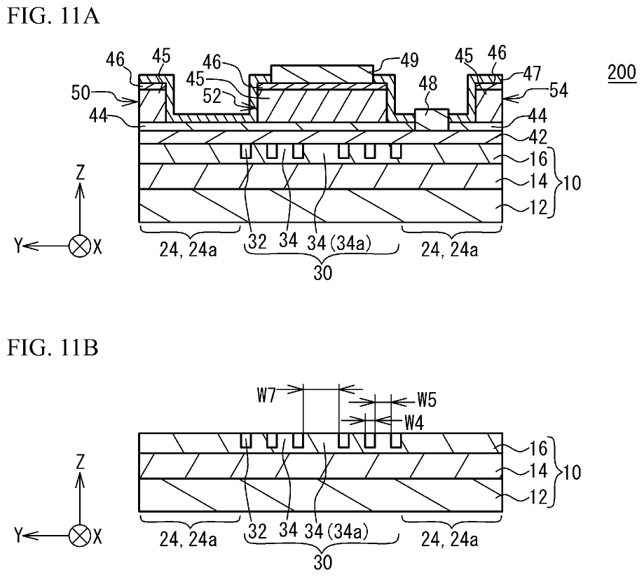

FIG. 11A is a cross-sectional view illustrating a semiconductor optical device 200 in accordance with the second embodiment, and illustrates a cross section corresponding to FIG. 1B. FIG. 11B is a cross-sectional view illustrating substrate 10. Description of the same configuration as in the first embodiment will be omitted. As illustrated in FIG. 11A and FIG. 11B, among the plurality of protrusions 34, protrusion 34a is located below the center of mesa 52 indicated by line segment S1. Protrusion 34a is wider than other protrusions 34. A width W5 of each protrusion 34 other than protrusion 34a illustrated in FIG. 11B is, for example, 0.3 μm. A width W7 of protrusion 34a is, for example, wider than 1.5 times or wider than 2 times the width W5.

According to the second embodiment, the thermal conductivity of protrusion 34 formed of Si is higher than that of air. Heat is easily transferred from semiconductor element 40 to Si layer 16, resulting in higher heat dissipation. The heat dissipation is further improved by disposing protrusion 34a having a larger width than the other protrusion 34 under mesa 52. The heat generated in mesa 52 can be efficiently dissipated through protrusion 34a. The provision of recesses 32 lowers the effective refractive index of the Si layer 16. Thus, the optical confinement to active layer 44 under mesa 52 becomes strong. It is possible to achieve both the heat dissipation and the optical confinement. Except for protrusion 34a, the plurality of protrusions 34 have the same width. The placement of protrusions 34 is symmetrical about the center of mesa 52 (line segment S1), and the placement of recesses 32 is also symmetrical. The mode of light is stabilized.

In each of the comparative example and the embodiments, an optical confinement coefficient and heat dissipation were calculated. In the Y-axis direction, an area having 5 μm wide including mesa 52 of semiconductor element 40 is assumed as a heat dissipation region that contributes to heat dissipation. The width of 5 μm is equal to the width of first region 30 in FIG. 1B.

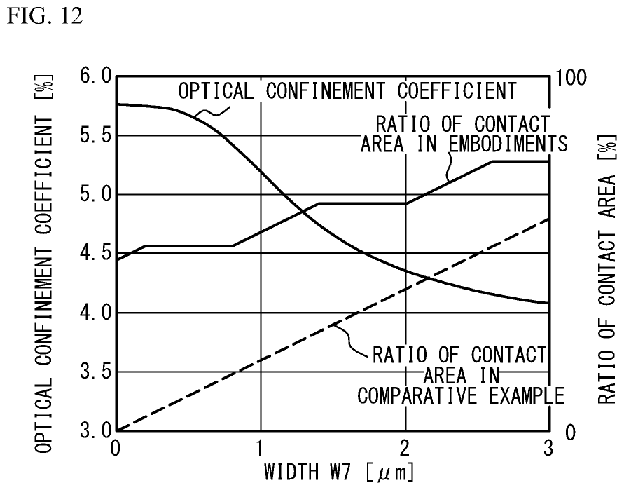

FIG. 12 illustrates the optical confinement coefficient and heat dissipation. A horizontal axis is the width of waveguide 20 in the comparative example or the width W7 of protrusion 34a in the embodiments. A left vertical axis is the optical confinement coefficient to active layer 44. A right vertical axis is a “ratio of contact area” which denotes a ratio of a contact area between substrate 10 and the semiconductor element 40 to an area of the heat dissipation region (area of 5 μm width). The higher the ratio of the contact area, the higher the heat dissipation. FIG. 12 illustrates the results of the calculation by varying the width W7. In the calculation, the width W6 of mesa 52 is 3 μm, the width W4 of recess 32 is 0.3 μm, and the width W5 of protrusion 34 other than protrusion 34a is 0.3 μm. The materials for substrate 10 and semiconductor element 40 are the same as those described in the first embodiment.

A curved line in FIG. 12 represents the optical confinement coefficient. The dotted line represents the ratio of contact area in the comparative example. The solid line represents the ratio of contact area in the embodiments. The comparative example is illustrated in FIG. 9. The embodiments include the first and second embodiments. Among the embodiments, the case where the width W7 is equal to the width W5 (0.3 μm) corresponds to the first embodiment. The case where the width W7 is greater than the width W5 corresponds to the second embodiment.

As illustrated in FIG. 12, the optical confinement coefficient decreases as the width W7 increases. In the comparative example illustrated in FIG. 9, waveguide 20 is provided directly below mesa 52. As illustrated in FIG. 1B, in the embodiment, protrusion 34a is located directly below mesa 52. Thus, as the width W7 increases, the light is more likely to leak from mesa 52 to substrate 10. On the other hand, as the width W7 increases, the ratio of contact area increases and the heat dissipation improves.

Even if the optical confinement coefficient is the same, the ratio of contact area in the comparative example is smaller than that in the embodiments. In other words, the heat dissipation in the comparative example is low, while the heat dissipations in the embodiments are high. As illustrated in FIG. 9, in the comparative example, grooves 22 are provided under semiconductor element 40. Since the amount of air under semiconductor element 40 is large, the heat dissipation becomes low. On the other hand, in the embodiments, as illustrated in FIG. 1B and the like, groove 22 is not provided under semiconductor 40, and the plurality of protrusions 34 are provided. The amount of air is reduced and the heat dissipation is increased. Depending on the desired optical confinement, the width W7 of protrusion 34a may be adjusted. When the width W7 of protrusion 34a is in a range of about 0.3 μm or more through 1.1 μm or less, the optical confinement coefficient is 5% or more, and the heat dissipation higher than that of the comparative example can be realized. When the width W7 is about 1.1 μm or more, the optical confinement coefficient is less than 5% but the heat dissipation becomes higher. When the width W7 is greater than or equal to 2 μm, the heat dissipation is further increased. On the other hand, the optical confinement coefficient decreases. In order to achieve both the high heat dissipation and the high optical confinement, the width W7 is set to be, for example, 1.2 times or more, 1.5 times or more, 2 times or more, or 10 times or less (3 μm or less) of the width W5 (0.3 μm in the example of FIG. 12).

### Third Embodiment

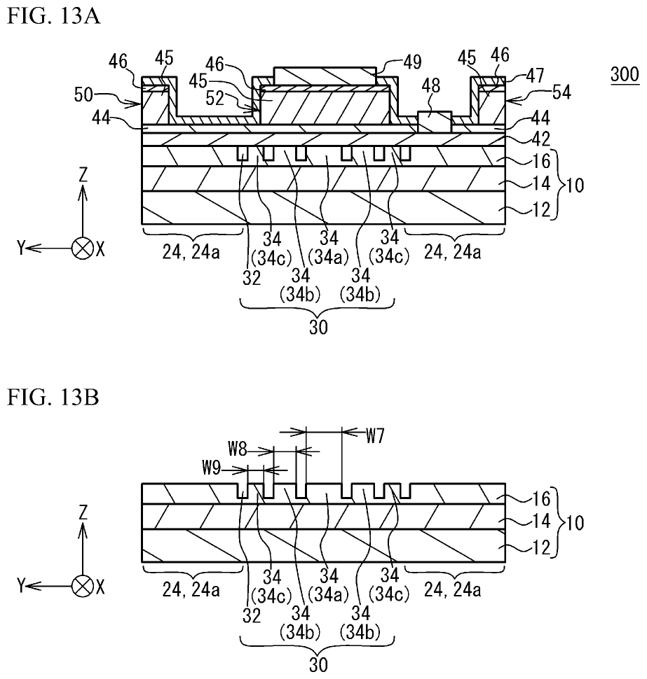

FIG. 13A is a cross-sectional view illustrating a semiconductor optical device 300 according to a third embodiment, and illustrates a cross section corresponding to FIG. 1B. FIG. 13B is a cross-sectional view illustrating substrate 10. Description of the same configuration as in the first embodiment will be omitted. As illustrated in FIGS. 13A and 13B, the plurality of protrusions 34 includes one protrusion 34a, two protrusions 34b, and two protrusions 34c. Protrusion 34a is located below mesa 52. Two protrusions 34b are located on both sides of protrusion 34a in the Y-axis direction. Two protrusions 34c are located outside protrusions 34b in the Y-axis direction. That is, one of protrusions 34c, one of protrusions 34b, protrusion 34a, the other of protrusions 34b, and the other of protrusions 34c are arranged in order from one side to the other side in the Y-axis direction.

Among the plurality of protrusions 34, the width W7 of protrusion 34a is the largest. A width W8 of the protrusion 34b is smaller than the width W7 of protrusion 34a and larger than a width W9 of protrusion 34c. Among the plurality of protrusions 34, the width W9 of protrusion 34c is the smallest. The width W9 of protrusion 34c illustrated in FIG. 13B is, for example, 0.3 μm. The width W7 of protrusion 34a is, for example, 1.5 times or more, 2 times or more, or the like of the width W9. The width W8 of protrusion 34b is, for example, 1.2 times or more of the width W9, and is less than the width W7. Each width of recesses 32 is, for example, 0.3 μm.

According to the third embodiment, protrusions 34 formed of Si have higher thermal conductivity than air. Heat is easily transferred from semiconductor element 40 to Si layer 16, resulting in higher heat dissipation. The widest protrusion 34a among the plurality of protrusions 34 is located directly below mesa 52. Next to protrusion 34a, two protrusions 34b are located. The narrowest protrusion 34c among the plurality of protrusions 34 is located outside protrusion 34b. That is, protrusion 34a, protrusion 34b, and protrusion 34c are arranged in this order from the side close to the center of mesa 52 toward outside of mesa 52. Among the plurality of protrusions 34, protrusions closer to the center of mesa 52 have larger widths, so that the heat dissipation is further improved and heat generated in mesa 52 can be efficiently dissipated. The arrangement of the protrusions 34 is symmetrical with respect to mesa 52. The mode of light is stabilized. Since recesses 32 are provided, the effective refractive index of Si layer 16 decreases. Thus, the optical confinement to active layer 44 under mesa 52 becomes stronger. It is possible to achieve both heat dissipation and optical confinement.

The present disclosure is not limited to the specific embodiments described above, but various variations and changes are possible within the scope of the gist of the present disclosure as described in the claims.

What is claimed is:

1. A semiconductor optical device comprising:
a substrate containing silicon; and
a semiconductor element bonded to the substrate, the semiconductor element being formed of a compound semiconductor, and having an optical gain,
wherein the substrate includes a waveguide and a first region connected to the waveguide in an extension direction of the waveguide,
wherein the first region includes a plurality of recesses and a plurality of protrusions,
wherein each of the plurality of recesses is recessed in a thickness direction of the substrate compared to a surface of the substrate to which the semiconductor element is bonded,
wherein each of the plurality of protrusions protrudes in the thickness direction of the substrate compared to bottom surfaces of the plurality of recesses,
wherein the plurality of recesses and the plurality of protrusions are alternately disposed in a direction intersecting with the extension direction of the waveguide, and
wherein the semiconductor element is bonded to the first region.

2. The semiconductor optical device according to claim 1,
wherein the substrate includes a silicon layer, and
wherein the waveguide, the plurality of protrusions, and the plurality of recesses are provided in the silicon layer.

3. The semiconductor optical device according to claim 1,
wherein the substrate includes a second region and a groove,
wherein the groove is located on either of both sides of the waveguide in the direction intersecting with the extension direction of the waveguide,
wherein the second region is located on a side opposite to the waveguide with respect to the groove,
wherein the first region is connected to the second region in the direction intersecting with the extension direction of the waveguide, and
wherein the semiconductor element is bonded to the first region and the second region.

4. The semiconductor optical device according to claim 3, wherein the semiconductor element is in contact with upper surfaces of the plurality of protrusions and an upper surface of the second region.

5. The semiconductor optical device according to claim 1,
wherein the semiconductor element includes a first cladding layer having a first conductive type, an active layer, and a second cladding layer having a second conductive type,
wherein the first cladding layer, the active layer, and the second cladding layer are stacked in this order from a side close to the substrate,
wherein the semiconductor element includes a mesa,
wherein the mesa is located on the first region, protrudes from the side close to the substrate toward a side opposite to the substrate, and includes the second cladding layer, and
wherein the semiconductor optical device comprises
a first electrode electrically connected to the first cladding layer, and
a second electrode electrically connected to the second cladding layer of the mesa.

6. The semiconductor optical device according to claim 5, wherein a width of the first region in the direction intersecting with the extension direction of the waveguide is larger than a width of the mesa.

7. The semiconductor optical device according to claim 5, wherein the plurality of protrusions include a first protrusion located at a center in the direction intersecting with the extension direction of the waveguide, the first protrusion being located under the mesa.

8. The semiconductor optical device according to claim 7, wherein a width of the first protrusion is larger than widths of the protrusions other than the first protrusion.

9. The semiconductor optical device according to claim 5, wherein the plurality of protrusions have larger widths as the plurality of protrusions are located closer to a center of the mesa.

10. The semiconductor optical device according to claim 5,
wherein the plurality of recesses are disposed symmetrically with respect to the mesa in the direction intersecting with the extension direction of the waveguide, and
wherein the plurality of protrusions are disposed symmetrically with respect to the mesa in the direction intersecting with the extension direction of the waveguide.

11. The semiconductor optical device according to claim 1,
wherein the first region includes a tapered portion,
wherein the tapered portion is tapered from the first region toward the waveguide in the extension direction of the waveguide,
wherein the waveguide is connected to a distal end of the tapered portion, and
wherein end portions of the recesses and end portions of the protrusions in the extension direction of the waveguide are located in the tapered portion.

12. A method for manufacturing a semiconductor optical device, comprising:
a step of preparing a substrate containing silicon; and
a step of bonding a semiconductor element formed of a compound semiconductor and having an optical gain to the substrate,
wherein the substrate includes a waveguide and a first region connected to the waveguide in an extension direction of the waveguide,
wherein the first region includes a plurality of recesses and a plurality of protrusions,
wherein the recesses are recessed in a thickness direction of the substrate compared to a surface of the substrate to which the semiconductor element is bonded,
wherein the protrusions protrude in the thickness direction of the substrate compared to bottom surfaces of the recesses,
wherein the plurality of recesses and the plurality of protrusions are alternately disposed in a direction intersecting with the extension direction of the waveguide, and
wherein the semiconductor element is bonded to the first region in the step of bonding the semiconductor element to the substrate.
